(19) United States
(12) Patent Application Publication
(10) Pub. No.: US 2026/0169385 A1
(43) Pub. Date: Jun. 18, 2026

(54) METHOD FOR MANUFACTURING SEMICONDUCTOR SUBSTRATE AND UNDERLAYER FILM-FORMING COMPOSITION

(71) Applicant: JSR CORPORATION, Tokyo (JP)

(72) Inventors: Tatsuya KASAI, Tokyo (JP); Kazuya TAKADA, Tokyo (JP)

(73) Assignee: JSR CORPORATION, Tokyo (JP)

(21) Appl. No.: 19/529,247

(22) Filed: Feb. 4, 2026

Related U.S. Application Data
(63) Continuation-in-part of application No. PCT/JP2024/025960, filed on Jul. 19, 2024.

(30) Foreign Application Priority Data
Aug. 9, 2023 (JP) 2023-129870

(51) Int. Cl. G03F 7/11; G03F 7/004; G03F 7/075; G03F 7/20; H10P 76/20

(52) U.S. Cl. CPC G03F 7/11; G03F 7/0042; G03F 7/0752; G03F 7/2004; H10P 76/2042; H10P 76/2043

(57) ABSTRACT

A method for manufacturing a semiconductor substrate includes: applying an underlayer film-forming composition directly or indirectly to a substrate to form an underlayer film; forming a metal-containing resist film on the underlayer film; exposing the metal-containing resist film to extreme ultraviolet rays; and developing the exposed metal-containing resist film. The underlayer film-forming composition includes: a compound including a structural unit (α) represented by formula (1-1); and a solvent. In the formula (1-1), a is an integer of 1 to 3; R¹ is a monovalent organic group having 1 to 20 carbon atoms, a hydroxy group, or a halogen atom; b is an integer of 0 to 2; when b is 2, two R¹s are the same or different from each other; provided that a+b is 3 or less.

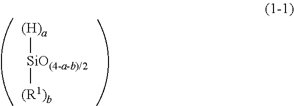

### CROSS-REFERENCE TO RELATED APPLICATIONS

The present application is a continuation-in-part application of International Patent Application No. PCT/JP2024/025960 filed Jul. 19, 2024, which claims priority to Japanese Patent Application No. 2023-129870 filed Aug. 9, 2023. The contents of these applications are incorporated herein by reference in their entirety.

### BACKGROUND OF THE DISCLOSURE

### Technical Field

The present disclosure relates to a method for manufacturing a semiconductor substrate and an underlayer film-forming composition.

### Background Art

For pattern formation in the manufacture of semiconductor substrates, for example, a multilayer resist process or the like is used in which a patterned substrate is formed by etching using, as a mask, a resist pattern obtained by exposing and developing a resist film laminated on a substrate via an organic underlayer film, a silicon-containing film, and the like (WO2022/260154).

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Accordingly, a metal-containing resist film is being used instead of the organic resist film.

While the line width of a resist pattern formed through exposure to extreme ultraviolet rays and development is being miniaturized, an underlayer film for a metal-containing resist is required to have pattern rectangularity of securing rectangularity of a resist pattern by suppressing trailing of the pattern at the bottom of a resist film and development residues.

### SUMMARY

According to an aspect of the present disclosure, a method for manufacturing a semiconductor substrate includes: applying an underlayer film-forming composition (hereinafter, also referred to as a “composition”) directly or indirectly to a substrate to form an underlayer film; forming a metal-containing resist film on the underlayer film; exposing the metal-containing resist film to extreme ultraviolet rays; and developing the exposed metal-containing resist film. The underlayer film-forming composition includes: a compound including a structural unit (α) represented by formula (1-1) (hereinafter, also referred to as “compound [A]”); and a solvent (hereinafter, also referred to as “solvent [B]”).

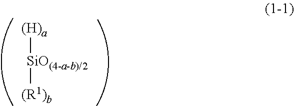

In the formula (1-1), a is an integer of 1 to 3; R¹ is a monovalent organic group having 1 to 20 carbon atoms, a hydroxy group, or a halogen atom; b is an integer of 0 to 2; when b is 2, two R¹s are the same or different from each other; provided that a+b is 3 or less.

According to another aspect of the present disclosure, a underlayer film-forming composition includes: a compound including a structural unit (α) represented by formula (1-1); and a solvent.

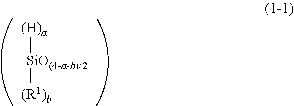

In the formula (1-1), a is an integer of 1 to 3; R¹ is a monovalent organic group having 1 to 20 carbon atoms, a hydroxy group, or a halogen atom; b is an integer of 0 to 2; when b is 2, two R¹s are the same or different from each other; provided that a+b is 3 or less.

### DETAILED DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed.

Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In the method for manufacturing a semiconductor substrate, the underlayer film-forming composition for a metal-containing resist includes a compound [A] being a polysiloxane or polycarbosilane containing a structural unit (α) having a hydrosilane (Si—H) structure. Thanks to this, an underlayer film for a metal-containing resist capable of exhibiting excellent pattern rectangularity is formed, and that makes it possible to efficiently manufacture a high-quality semiconductor substrate. The reason for this is not clear, but can be presumed as follows. When some interaction site (for example, a hydroxy group or the like) is generated in the exposed portion of the metal-containing resist film having been exposed to light, a hydrogen bond or other interaction works between this interaction site and a hydrogen atom in the structural unit (α) of the underlayer film for a metal-containing resist. As a result, it is presumed that superior organic solvent developability is obtained, resist residues are suppressed, and good pattern rectangularity can be exhibited while adhesion between the underlayer film for a metal-containing resist and the metal-containing resist film is enhanced.

According to the composition for forming an underlayer film for a metal-containing resist film, an underlayer film for a metal-containing resist film having a good resist pattern rectangularity can be efficiently formed.

In the present specification, an “organic group” is referred to as a group having at least one carbon atom and a “carbon number” is referred to as the number of carbon atoms constituting a group.

Hereinafter, a method for manufacturing a semiconductor substrate and an underlayer film-forming composition for a metal-containing resist according to embodiments of the present disclosure will be described in detail. Combinations of suitable modes in embodiments are also preferred.

### <<Method for Manufacturing Semiconductor Substrate>>

The method for manufacturing a semiconductor substrate according to the present embodiment includes: applying an underlayer film-forming composition for a metal-containing resist directly or indirectly to a substrate (hereinafter also referred to as “application step”); forming a metal-containing resist film on the underlayer film for a metal-containing resist formed by applying the underlayer film-forming composition for a metal-containing resist (hereinafter also referred to as “metal-containing resist film forming step”); exposing the metal-containing resist film to extreme ultraviolet rays (hereinafter also referred to as “exposing step”); and developing at least the exposed metal-containing resist film (hereinafter also referred to as “developing step”).

The method for manufacturing a semiconductor substrate may further include, if necessary, directly or indirectly forming an organic underlayer film on the substrate (hereinafter, also referred to as an “organic underlayer film forming step”) before the application step (I).

Further, the method for manufacturing a semiconductor substrate may further include, after the developing step, etching the underlayer film for a metal-containing resist using the resist pattern as a mask to form a pattern of the underlayer film for a metal-containing resist (hereinafter, also referred to as a “step of forming a pattern of the underlayer film for a metal-containing resist”), and performing etching using the pattern of the underlayer film for a metal-containing resist as a mask (hereinafter, also referred to as an “etching step”).

According to the method for manufacturing a semiconductor substrate, an underlayer film for a metal-containing resist that is excellent in pattern rectangularity can be formed by using the composition in the step of forming an underlayer film for a metal-containing resist.

Hereinafter, description will be made about the underlayer film-forming composition for a metal-containing resist to be used in the method for manufacturing a semiconductor substrate; and a case where optional steps, namely, an organic underlayer film forming step before the application step, and a step of forming a pattern of an underlayer film for a metal-containing resist and an etching step after the developing step are included.

### <Underlayer Film-Forming Composition for Metal-Containing Resist>

The composition contains a compound [A] and a solvent [B]. The composition may further contain other optional components as long as the effects of the present invention are not impaired.

The composition is suitably used for forming an underlayer film for a metal-containing resist, as the underlayer film of the metal-containing resist film. Each component contained in the composition will be described below.

### <Compound [A]>

The compound [A] has at least the structural unit (α). The compound [A] is preferably polysiloxane. In the following, each structural unit of the compound [A] will be described. As used herein, “polysiloxane” means a compound containing a siloxane bond (—Si—O—Si—).

### (Structural Unit (α))

The structural unit (α) is represented by formula (1-1). The compound [A] may contain one type or two or more types of the structural unit (α).

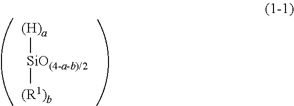

In the formula (1-1), a is an integer of 1 to 3. R¹ is a monovalent organic group having 1 to 20 carbon atoms, a hydroxy group, or a halogen atom. b is an integer of 0 to 2. When b is 2, two R¹s are the same or different from each other. It is noted that a+b is 3 or less.

In the formula (1-1), examples of the monovalent organic group having 1 to 20 carbon atoms represented by R¹ include: a monovalent hydrocarbon group having 1 to 20 carbon atoms;
a group containing a divalent heteroatom-containing linking group between carbon and carbon of the hydrocarbon group (hereinafter also referred to as “group (α)”);
a group in which some or all hydrogen atoms of the hydrocarbon group or the group (α) are replaced with a monovalent heteroatom-containing substituent (hereinafter also referred to as “group (β)”); and
a group in which at least two among the hydrocarbon group, the group (α), and the group (β) are combined (hereinafter also referred to as “group (γ)”).

Examples of the monovalent hydrocarbon group having 1 to 20 carbon atoms include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group having 1 to 20 carbon atoms include a monovalent chain aliphatic saturated hydrocarbon group having 1 to 20 carbon atoms and a monovalent chain aliphatic unsaturated hydrocarbon group having 1 to 20 carbon atoms. Examples of the monovalent chain aliphatic saturated hydrocarbon group having 1 to 20 carbon atoms include alkyl groups such as a methyl group, an ethyl group, a n-propyl group, an isopropyl group, a n-butyl group, a sec-butyl group, an isobutyl group, and a tert-butyl group. Examples of the monovalent chain aliphatic unsaturated hydrocarbon group having 1 to 20 carbon atoms include alkenyl groups such as an ethenyl group, a propenyl group, and a butenyl group; and alkynyl groups such as an ethynyl group, a propynyl group, and a butynyl group.

Examples of monovalent alicyclic hydrocarbon groups having 3 to 20 carbon atoms include monocyclic saturated alicyclic hydrocarbon groups such as cyclopentyl group and cyclohexyl group, polycyclic alicyclic saturated hydrocarbon groups such as a norbornyl group, an adamantyl group, a tricyclodecyl group, a tetracyclododecyl group, monocyclic alicyclic unsaturated hydrocarbon groups such as a cyclopentenyl group and a cyclohexenyl group, polycyclic alicyclic unsaturated hydrocarbon groups such as a norbornenyl group, a tricyclodecenyl group, a tetracyclododesenyl group.

Examples of monovalent aromatic hydrocarbon groups having 6 to 20 carbon atoms include aryl groups such as a phenyl group, a tolyl group, a xylyl group, a naphthyl group and an anthryl group, aralkyl groups such as a benzyl group, a phenethyl group, a naphthylmethyl group and an anthrylmethyl group.

Examples of the heteroatoms that constitute the divalent heteroatom-containing linking group and the monovalent heteroatom-containing substituent include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom (in this specification, unless otherwise specified, the term “halogen atom” includes these atoms.).

Examples of the divalent heteroatom-containing liking groups include, for example, —O—, —C(═O)—, —S—, —C(═S)—, —NR′—, —SO₂—, or combinations of two or more of these and the like. R′ is a hydrogen atom or a monovalent hydrocarbon group.

Examples of the monovalent hetero atom-containing substituent include a halogen atom, a hydroxy group, a carboxy group, a cyano group, an amino group, and a sulfanyl group.

The number of the carbon atoms of the monovalent organic group represented by R¹ is preferably 1 to 10, and more preferably 1 to 6.

As the halogen atom represented by R¹, a chlorine atom is preferable.

R¹ is preferably a monovalent chain hydrocarbon group, a monovalent aromatic hydrocarbon group, or a monovalent group in which some or all of the hydrogen atoms of the monovalent hydrocarbon group are replaced with a monovalent hetero atom-containing group, more preferably an alkyl group or an aryl group, further preferably a methyl group, an ethyl group, or a phenyl group, and particularly preferably a methyl group or an ethyl group.

In the formula (1-1), a is preferably 1 or 2, and more preferably 1.

In the formula (1-1), b is preferably 0 or 1, and more preferably 0.

Examples of the structural unit (α) include structural units derived from the compounds represented by the following formulas (1-1-1) to (1-1-3) (hereinafter also referred to as “structural units (α-1) to (α-3)”).

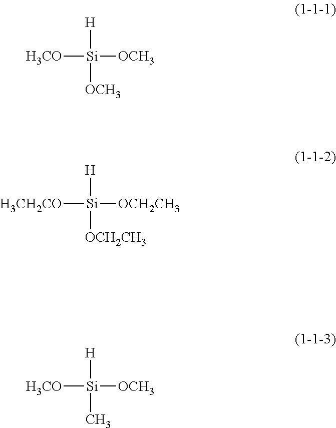

The lower limit of the content ratio of the structural unit (α) (when there is a plurality of types of the structural unit (α), the total content ratio is taken) to all the structural units constituting the compound [A] is preferably 0.1 mol %, more preferably 1 mol %, and still more preferably 3 mol %. The upper limit of the content ratio may be 100 mol %, and is preferably 90 mol %, more preferably 50 mol %, still more preferably 40 mol %, and particularly preferably 30 mol %. When the content ratio of the structural unit (α) is adjusted to within the above range, the pattern rectangularity can be further improved.

### (Structural Unit (β))

The compound [A] preferably has a structural unit (β) represented by formula (2-1). The compound [A] may have one type or two or more types of the structural unit (β).

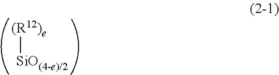

(In the formula (2-1), R¹² is a monovalent organic group having 1 to 20 carbon atoms, a hydroxy group, or a halogen atom; e is an integer of 0 to 3; when e is 2 or more, the plurality of R¹²s is the same or different from each other.)

As the monovalent organic group having 1 to 20 carbon atoms represented by R¹², a monovalent organic group having 1 to 20 carbon atoms represented by R¹ of the above formula (1-1) can be suitably employed.

R¹² is preferably a substituted or unsubstituted monovalent alkoxy group having 1 to 20 carbon atoms, a substituted or unsubstituted aryl group having 6 to 20 carbon atoms, or a substituted or unsubstituted alkyl group having 1 to 10 carbon atoms.

Examples of the monovalent alkoxy group having 1 to 20 carbon atoms include alkoxy groups such as a methoxy group, an ethoxy group, an n-propoxy group, and an isopropoxy group.

Examples of the aryl group having 6 to 20 carbon atoms include a phenyl group, a naphthyl group, and an anthracenyl group.

Examples of the alkyl group having 1 to 10 carbon atoms include a methyl group, an ethyl group, an n-propyl group, an i-propyl group, an n-butyl group, an i-butyl group, and a t-butyl group.

When the alkoxy group, the aryl group, and the alkyl group have a substituent, the monovalent heteroatom-containing substituent described above can be suitably employed as the substituent. Further, examples of the substituent of the aryl group include an alkyl group, an alkoxy group, an alkoxycarbonyl group, an alkoxycarbonyloxy group, an acyl group, an acyloxy group, and a group obtained by replacing a hydrogen atom of these groups with a halogen atom.

e is preferably an integer of 0 to 2, and more preferably 0 or 1. The compound [A] preferably has, as the structural unit (β), a structural unit in which e in the formula (2-1) is 0 (hereinafter also referred to as “structural unit (β-e0)”) and a structural unit in which e is 1 (hereinafter also referred to as “structural unit (β-e1)”) in combination.

Examples of the structural unit (β) include structural units derived from the compounds represented by the following formulas (2-1-1) to (2-1-2026) (hereinafter also referred to as “structural units (2-1-1) to (2-1-2026)”).

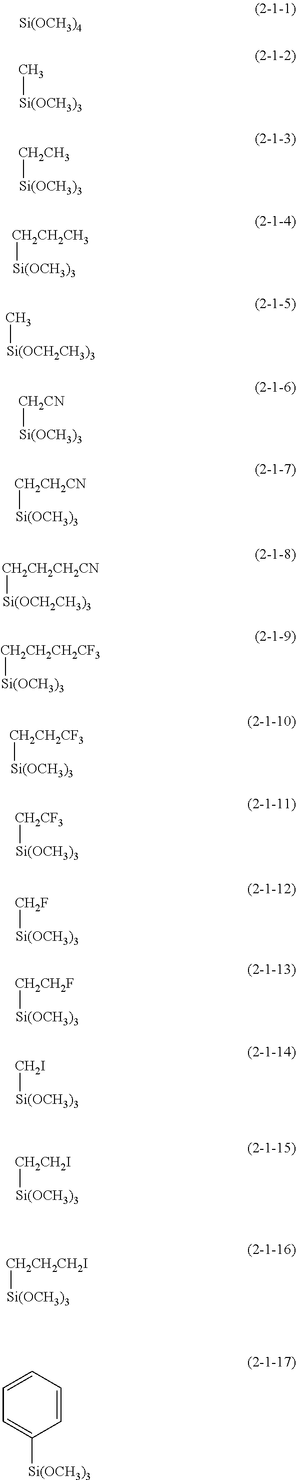

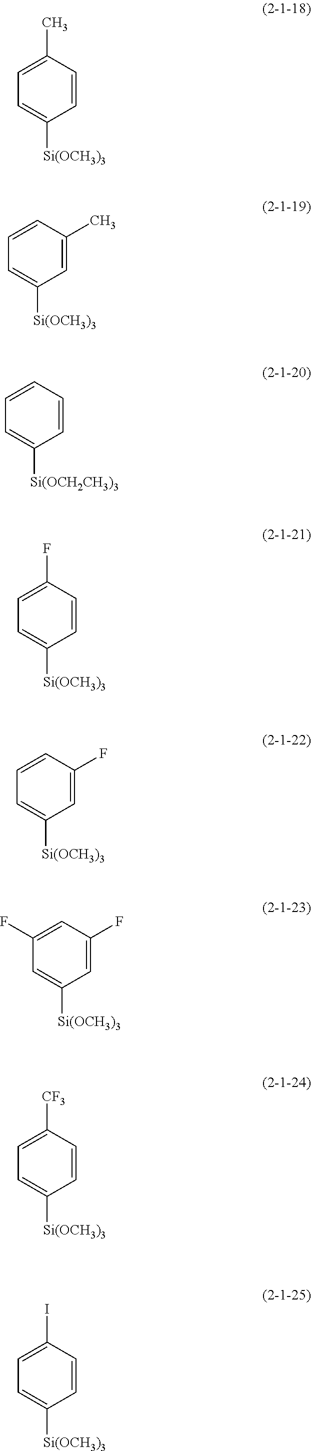

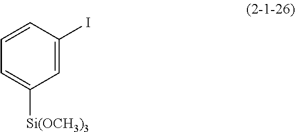

When the compound [A] has the structural unit (β-e0), the lower limit of the content ratio of the structural unit (β-e0) to all the structural units constituting the compound [A] is preferably 20 mol %, more preferably 30 mol %, still more preferably 40 mol %, and particularly preferably 50 mol %. The upper limit of the content ratio of the structural unit (β-e0) is preferably 95 mol %, more preferably 90 mol %, and still more preferably 85 mol %.

When the compound [A] has the structural unit (β-e1), the lower limit of the content ratio of the structural unit (β-e1) ((when there is a plurality of types of the structural unit (β-e1), the total content ratio is taken)) to all the structural units constituting the compound [A] is preferably 5 mol %, more preferably 10 mol %, and still more preferably 12 mol %. The upper limit of the content ratio of the structural unit (β-e1) is preferably 80 mol %, more preferably 70 mol %, and still more preferably 60 mol %.

The lower limit of the content ratio of the compound [A] is preferably 0.05% by mass, more preferably 0.1% by mass, and still more preferably 0.3% by mass based on the total mass of the compound [A] and the solvent [B]. The upper limit of the content ratio is preferably 5% by mass, more preferably 3% by mass, and still more preferably 18 by mass.

The compound [A] is preferably in the form of a polymer. The term “polymer” refers to a compound having two or more structural units, and when two or more identical structural units are consecutive in a polymer, the structural units are also referred to as “repeating units”. When the compound [A] is in the form of a polymer, the lower limit of the polystyrene-equivalent weight-average molecular weight (Mw) of the compound [A] determined by gel permeation chromatography (GPC) is preferably 800, more preferably 1,000, still more preferably 1,200, and particularly preferably 1, 400. The upper limit of Mw is preferably 15,000, more preferably 10,000, still more preferably 7,000, and particularly preferably 4,000. The Mw of the compound [A] is measured as described in Examples.

### Synthesis of Compound [A]

The compound [A] can be synthesized by a conventional method using monomers that afford the respective structural units. For example, it can be synthesized by hydrolyzing and condensing a monomer that affords the structural unit (α) and, as necessary, a monomer that affords another structural unit in a solvent in the presence of water and a catalyst such as oxalic acid, and preferably purifying a solution containing the generated hydrolysis-condensation product by solvent replacement or the like in the presence of a dehydrating agent such as trimethyl orthoformate. It is considered that each monomer is incorporated into the compound [A] regardless of the type thereof by a hydrolysis condensation reaction or the like. Therefore, the content ratios of the first structural unit and the other structural unit in the synthesized compound [A] are usually equivalent to the proportions of the charged amounts of the respective monomers used in the synthesis reaction.

### <Solvent [B]>

Examples of the solvent [B] include alcohol-based solvents, ketone-based solvents, ether-based solvents, ester-based solvents, nitrogen-containing solvents, and water. The solvent [B] may be used singly or two or more kinds thereof may be used in combination.

Examples of alcohol solvents include monoalcohol solvents such as methanol, ethanol, n-propanol, iso-propanol, n-butanol and iso-butanol, polyhydric alcohol solvents such as ethylene glycol, 1,2-propylene glycol, diethylene glycol and dipropylene glycol.

Examples of ketone solvents include acetone, 2-butanone, 2-pentanone, 4-methyl-2-pentanone, 2-heptanone, and cyclohexanone.

Examples of ether solvents include ethyl ether, iso-propyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran and the like.

Examples of ester solvents include ethyl acetate, γ-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate and the like.

Examples of nitrogen-containing solvents include N, N-dimethylformamide, N, N-dimethylacetamide, N-methylpyrrolidone, and the like.

Among these, ether-based solvents or ester-based solvents are preferable, and ether-based solvents or ester-based solvents having a glycol structure are more preferable because of their excellent film-forming properties.

Examples of ether solvents and ester solvents having a glycol structure include propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate and the like. Among these, propylene glycol monomethyl ether acetate or propylene glycol monoethyl ether is preferable.

The total content ratio of the ether-based solvent having a glycol structure and the ester-based solvent in the solvent [B] is preferably 208 by mass or more, more preferably 60% by mass or more, still more preferably 90% by mass or more, and particularly preferably 100% by mass.

The lower limit of the content ratio of the solvent [B] in the composition is preferably 50% by mass, more preferably 80% by mass, still more preferably 90% by mass, and particularly preferably 95% by mass. The upper limit of the content ratio is preferably 99.9% by mass, more preferably 99% by mass, and further preferably 98% by mass.

### <Other Optional Components>

Examples of other optional components include acid generators, basic compounds (including base generators), ortho esters, radical generators, surfactants, colloidal silica, colloidal alumina, and organic polymers. The other optional components may be used singly or two or more kinds thereof may be used in combination.

### (Acid Generator)

The acid generator is a component that generates an acid through exposure to light or heating. When the composition contains an acid generator, the condensation reaction of the compound [A] can be promoted even at a relatively low temperature (including normal temperature).

Examples of the acid generator that generates an acid through exposure to light (hereinafter also referred to as “photo-acid generator”) include the acid generators described in paragraphs [0077] to [0081] in JP-A-2004-168748, triphenylsulfonium trifluoromethanesulfonate, and compounds represented by the following formulae.

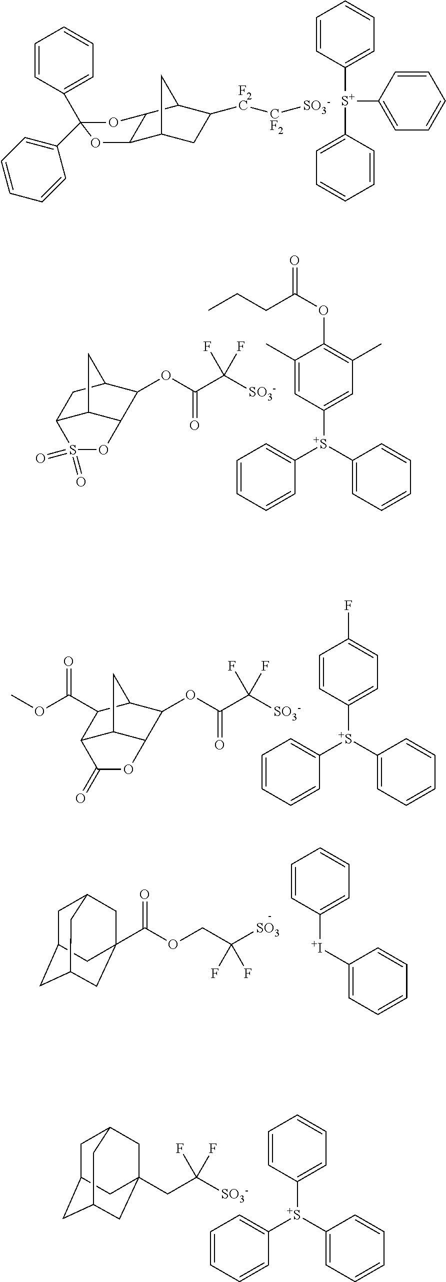

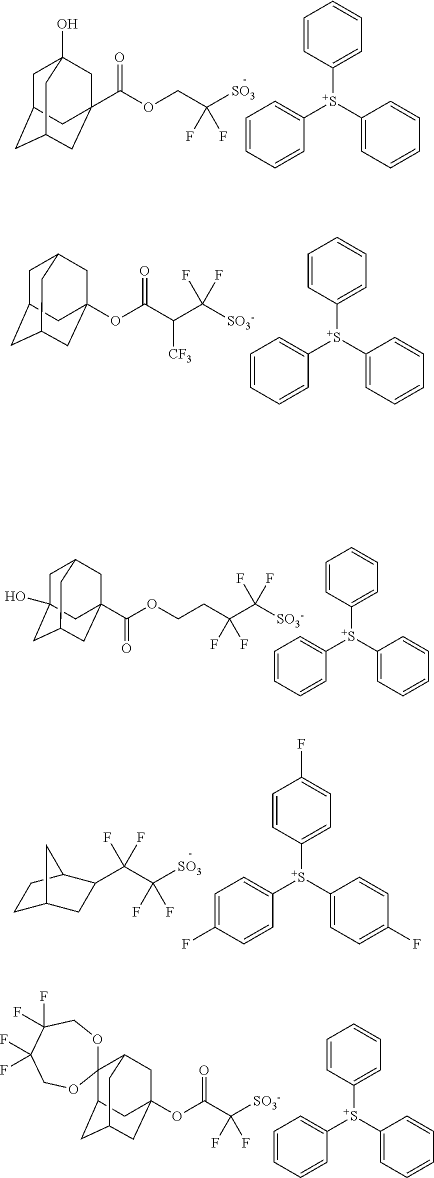

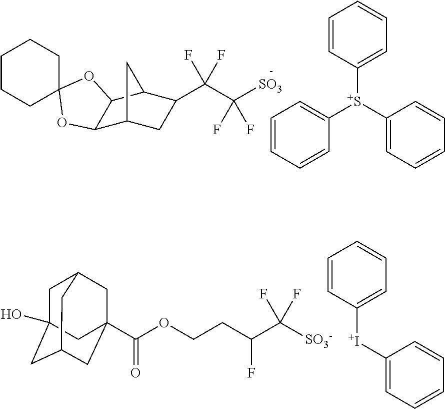

Examples of the acid generator that generates an acid through heating (hereinafter also referred to as “thermal acid generator”) include onium salt-based acid generators recited as examples of photo-acid generators in the above-cited Patent Document, 2,4,4,6-tetrabromocyclohexadienone, benzoin tosylate, 2-nitrobenzyl tosylate, and alkyl sulfonates.

When the composition comprises an acid generator, the lower limit of the content of the acid generator is preferably 10 parts by mass, more preferably 50 parts by mass, and still more preferably 100 parts by mass based on 100 parts by mass of the compound [A]. The upper limit of the content of the acid generator is preferably 1000 parts by mass, and more preferably 800 parts by mass based on 100 parts by mass of the compound [A].

### Basic Compound

The basic compound promotes a curing reaction of the composition, and as a result, enhance the strength or the like of a film to be formed. In addition, the basic compound improves the peelability of the film with an acidic solution. Examples of the basic compound include a compound having a basic amino group, and a base generator that generates a compound having a basic amino group by the action of an acid or the action of heat. Examples of the compound having a basic amino group include amine compounds. Examples of the base generator include an amide group-containing compound, a urea compound, and a nitrogen-containing heterocyclic compound. Examples of the amine compound, the amide group-containing compound, the urea compound, and the nitrogen-containing heterocyclic compound include compounds described in paragraphs [0079] to [0082] of JP-A-2016-27370.

When the composition comprises a basic compound, the lower limit of the content of the basic compound is preferably 10 parts by mass, more preferably 50 parts by mass, and still more preferably 100 parts by mass based on 100 parts by mass of the compound [A]. The upper limit of the content of the acid generator is preferably 1000 parts by mass, and more preferably 800 parts by mass based on 100 parts by mass of the compound [A].

### (Ortho Ester)

The ortho ester is an ester form of an orthocarboxylic acid. The ortho ester reacts with water to afford a carboxylate ester or the like. Examples of the ortho ester include orthoformate esters such as methyl orthoformate, ethyl orthoformate, and propyl orthoformate, orthoacetate esters such as methyl orthoacetate, ethyl orthoacetate, and propyl orthoacetate, and orthopropionate esters such as methyl orthopropionate, ethyl orthopropionate, and propyl orthopropionate. Among them, an orthoformate is preferable, and trimethyl orthoformate is more preferable.

When the composition comprises an ortho ester, the lower limit of the content of the ortho ester is preferably 10 parts by mass, more preferably 50 parts by mass, and still more preferably 100 parts by mass based on 100 parts by mass of the compound [A]. The upper limit of the content of the acid generator is preferably 1000 parts by mass, and more preferably 800 parts by mass based on 100 parts by mass of the compound [A].

### <Method for Preparing a Underlayer Film-Forming Composition for a Metal-Containing Resist>

The method for preparing the composition is not particularly limited, and for example, the composition can be prepared by mixing a solution of the compound [A], the solvent [B], and other optional components which are used as necessary in a prescribed ratio, and then filtering the resulting mixed solution through a filter having a pore size of 0.4 μm or less.

### [Organic Underlayer Film Forming Step]

In this step, an organic underlayer film is formed directly or indirectly on the substrate before the application step. This step is an arbitrary step. Through this step, an organic underlayer film is formed directly or indirectly on the substrate.

The organic underlayer film can be formed by applying a composition for forming an organic underlayer film. The method of forming the organic underlayer film by applying the composition for forming an organic underlayer film may be, for example, a method in which a coating film formed by directly or indirectly applying the composition for forming an organic underlayer film to a substrate is cured by heating or exposure. As the composition for forming an organic underlayer film, for example, “HM8006” manufactured by JSR Corporation can be used. Various conditions for heating or exposure can be appropriately determined according to the type of the composition for forming an organic underlayer film to be used.

Examples of a case where an organic underlayer film is indirectly formed on a substrate include a case where an organic underlayer film is formed on a low dielectric insulating film formed on a substrate.

### Application Step (I)

In this step, the underlayer film-forming composition for a metal-containing resist is applied directly or indirectly to the substrate. By this step, a coating film of the composition is formed directly or indirectly on the substrate, and the coating film is usually cured by heating to form an underlayer film for a metal-containing resist as a resist underlayer film.

Examples of substrates include insulating films such as silicon oxide, silicon nitride, silicon oxynitride and polysiloxane, and resin substrates. Also, the substrate may be a substrate having patterning such as a wiring groove (trench), a plug groove (vias) and the like.

The method for applying the underlayer film-forming composition for a metal-containing resist is not particularly limited, and examples thereof include a spin coating method.

Examples of the case where the underlayer film-forming composition for a metal-containing resist is applied indirectly to the substrate include a case where the underlayer film-forming composition for a metal-containing resist is applied to another film formed on the substrate. Other films formed on the substrate include, for example, an organic underlayer film which is formed by the organic underlayer film forming step described above, an antireflection film, a low dielectric insulating film, and the like.

When the coating film is heated, the atmosphere is not particularly limited, and examples thereof include air atmosphere, nitrogen atmosphere, and the like. Heating of the coating film is usually performed in the air atmosphere. Various conditions such as the heating temperature and the heating time when the coating film is heated can be appropriately determined. The lower limit of the heating temperature is preferably 90° C., more preferably 150° C., and even more preferably 200° C. The upper limit of the heating temperature is preferably 550° C., more preferably 450° C., and even more preferably 300° C. The lower limit of the heating time is preferably 15 seconds, more preferably 30 seconds. The upper limit of the heating time is preferably 1,200 seconds, more preferably 600 seconds.

When the underlayer film-forming composition for a metal-containing resist contains an acid generator, and the acid generator is a radiation-sensitive acid generator, the formation of the underlayer film for a metal-containing resist can be accelerated by combining heating and exposure. Radiation used for exposure includes, for example, the same radiation as exemplified in the exposing step described later.

The lower limit of the film thickness of the underlayer film for a metal-containing resist formed by this step is preferably 1 nm, more preferably 2 nm, and even more preferably 3 nm. The upper limit of the film thickness is preferably 30 nm, more preferably 10 nm, still more preferably 6 nm, and particularly preferably 5 nm. The method for measuring the film thickness of the underlayer film for a metal-containing resist is described in Examples.

### [Metal-Containing Resist Film Forming Step]

In this step, a metal-containing resist film is formed on the underlayer film for a metal-containing resist formed by the application step. The metal-containing resist film may be either a coating film or a vapor deposition film, but is preferably a coating film. The coating film can be formed by applying a composition for forming a metal-containing resist film (described later).

The method for applying the composition for forming a metal-containing resist film is not particularly limited, and examples thereof include a spin coating method.

To explain this step in more detail, for example, after applying a composition for forming a metal-containing resist film so that the formed metal-containing resist film has a predetermined thickness, pre-baking (hereinafter also referred to as “PB”) is performed to volatilize the solvent in the applied film to form a resist film.

The PB temperature and PB time can be appropriately determined according to the type of a composition for forming a metal-containing resist film used. The lower limit of the PB temperature is preferably 30° C., more preferably 50° C. The upper limit of the PB temperature is preferably 200° C., more preferably 150° C. The lower limit of the PB time is preferably 10 seconds, more preferably 30 seconds. The upper limit of the PB time is preferably 600 seconds, more preferably 300 seconds.

Examples of the composition for forming a metal-containing resist film used in this step include a composition for forming a metal-containing resist film including a compound containing a metal atom (hereinafter, also referred to as a “metal-containing compound [P]”).

### <Composition for Forming Metal-Containing Resist Film>

The composition for forming a metal-containing resist film contains a metal-containing compound [P]. The composition for forming a metal-containing resist film preferably further contains a solvent [Q], and may further contain other components.

### (Metal-Containing Compound [P])

The metal-containing compound [P] is a compound containing a metal atom. The metal-containing compound [P] may be used singly or in combination of two or more kinds thereof. In addition, the metal atom constituting the metal-containing compound [P] may be used singly or in combination of two or more kinds thereof. Here, the “metal atom” is a concept including a metalloid, that is, boron, silicon, germanium, arsenic, antimony, and tellurium.

The metal atom constituting the metal-containing compound [P] is not particularly limited. Examples thereof include metal atoms of Groups 3 to 16. Specific examples of the metal atom include a metal atom of Group 4 such as titanium, zirconium, and hafnium; a metal atom of Group 5 such as tantalum; a metal atom of Group 6 such as chromium and tungsten; a metal atom of Group 8 such as iron and ruthenium; a metal atom of Group 9 such as cobalt; a metal atom of Group 10 such as nickel; a metal atom of Group 11 such as copper; a metal atom of Group 12 such as zinc, cadmium, and mercury; a metal atom of Group 13 such as boron, aluminum, gallium, indium, and thallium; a metal atom of Group 14 such as germanium, tin, and lead; a metal atom of Group 15 such as antimony and bismuth; and a metal atom of Group 16 such as tellurium.

The metal atom constituting the metal-containing compound [P] preferably includes a first metal atom belonging to Group 4, Group 12, or Group 14 and belonging to Period 4, Period 5, or Period 6 in the periodic table. That is, the metal atom preferably contains at least one of titanium, zirconium, hafnium, zinc, cadmium, mercury, germanium, tin, and lead. As described above, the metal-containing compound [P] contains the first metal atom to further promote the release of secondary electrons in the exposed portion of the resist film and the change in solubility of the metal-containing compound [P] in a developer due to the secondary electrons and the like. As a result, the pattern rectangularity can be improved. The first metal atom is preferably tin or zirconium.

The metal-containing compound [P] preferably further has an atom other than the metal atom. Examples of the other atom include a carbon atom, a hydrogen atom, an oxygen atom, a nitrogen atom, a phosphorus atom, a sulfur atom, and a halogen atom. Among these atoms, a carbon atom, a hydrogen atom, and an oxygen atom are preferable. The other atom in the metal-containing compound [P] can be used singly or in combination of two or more kinds thereof.

When the composition for forming a metal-containing resist film includes: the metal-containing compound [P]; and the solvent [Q], the lower limit of the content ratio of the metal-containing compound [P] to components other than the solvent [Q] in the composition for forming a metal-containing resist film is preferably 50% by mass, more preferably 70% by mass, still more preferably 90% by mass, and particularly preferably 95% by mass. The content may be 100% by mass.

### Synthesis Method of Metal-Containing Compound [P]

The metal-containing compound [P] can be obtained, for example, by a method of performing a hydrolysis condensation reaction, a ligand exchange reaction, or the like on a metal compound having a metal atom and a hydrolyzable group, a hydrolysate of the metal compound, a hydrolysis condensation product of the metal compound, or a combination thereof. The metal compound can be used singly or in combination of two or more kinds thereof.

The metal-containing compound [P] is preferably derived from a metal compound having a metal atom and a hydrolyzable group and represented by formula (4) (hereinafter, also referred to as a “metal compound (1)”). By using such a metal compound (1), a stable metal-containing compound [P] can be obtained.

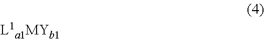

In the formula (4), M is a metal atom; L¹ is a ligand or a monovalent organic group having 1 to 20 carbon atoms; a1 is an integer of 0 to 6; when a1 is 2 or more, the plurality of Lis may be the same or different from each other; Y is a monovalent hydrolyzable group; b1 is an integer of 2 to 6; the plurality of Ys may be the same or different from each other; and L¹ is a ligand or an organic group that is not Y.

The metal atom represented by M is preferably the first metal atom, and more preferably tin.

The hydrolyzable group represented by Y can be appropriately changed according to the metal atom represented by M. Examples thereof include a substituted or unsubstituted ethynyl group, a halogen atom, an alkoxy group, an acyloxy group, and a substituted or unsubstituted amino group.

As the substituent in the substituted or unsubstituted ethynyl group and the substituted or unsubstituted amino group represented by Y, a monovalent hydrocarbon group having 1 to 20 carbon atoms is preferable, a chain hydrocarbon group is more preferable, and an alkyl group is still more preferable.

Examples of the halogen atom represented by Y include a fluorine atom, a chlorine atom, a bromine atom, and an iodine atom. Among them, a chlorine atom is preferable.

Examples of the alkoxy group represented by Y include a methoxy group, an ethoxy group, a n-propoxy group, an i-propoxy group, and a n-butoxy group. Among them, an ethoxy group, an i-propoxy group, and a n-butoxy group are preferable.

Examples of the acyloxy group represented by Y include a formyl group, an acetoxy group, an ethyryloxy group, a propionyloxy group, a n-butyryloxy group, a t-butyryloxy group, a t-amyryloxy group, a n-hexanecarbonyloxy group, and a n-octanecarbonyloxy group. Among them, an acetoxy group is preferable.

Examples of the substituted or unsubstituted amino group represented by Y include an amino group, a methylamino group, a dimethylamino group, a diethylamino group, and a dipropylamino group. Among them, a dimethylamino group and a diethylamino group are preferable.

Hereinafter, preferred combinations of the metal atom represented by M and the hydrolyzable group represented by Y will be described. When the metal atom represented by M is tin, the hydrolyzable group represented by Y is preferably a substituted or unsubstituted ethynyl group, a halogen atom, an alkoxy group, an acyloxy group, and a substituted or unsubstituted amino group, and more preferably a halogen atom. When the metal atom represented by M is germanium, the hydrolyzable group represented by Y is preferably a halogen atom, an alkoxy group, an acyloxy group, and a substituted or unsubstituted amino group. When the metal atom represented by M is hafnium, zirconium, and titanium, the hydrolyzable group represented by Y is preferably a halogen atom, an alkoxy group, and an acyloxy group.

Examples of the ligand represented by L¹ include a monodentate ligand and a multidentate ligand.

Examples of the monodentate ligand include a hydroxo ligand, a nitro ligand, and ammonia.

Examples of the multidentate ligand include a hydroxy acid ester, a β-diketone, a β-ketoester, a malonic acid diester in which a carbon atom at the α-position is optionally substituted, a hydrocarbon having a π bond, a ligand derived from these compounds, and a diphosphine.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, and 1,1′-bis(diphenylphosphino)ferrocene.

Examples of the monovalent organic group represented by L¹ include groups similar to the groups exemplified as the monovalent organic group having 1 to 20 carbon atoms represented by R¹ in the formula (1-1). The lower limit of the carbon number in the monovalent organic group represented by L¹ is preferably 2, and more preferably 3. On the other hand, the upper limit of the carbon number is preferably 10, and more preferably 5. The monovalent organic group represented by L¹ is preferably a substituted or unsubstituted hydrocarbon group, more preferably a substituted or unsubstituted chain hydrocarbon group or a substituted or unsubstituted aromatic hydrocarbon group, still more preferably a substituted or unsubstituted alkyl group or a substituted or unsubstituted aralkyl group, and particularly preferably an isopropyl group or a benzyl group.

a1 is preferably 1 or 2, and more preferably 1.

b1 is preferably an integer of 2 to 4. By setting b1 to the above numerical value, the content ratio of the metal atom in the metal-containing compound [P] can be increased, and the generation of secondary electrons by the metal-containing compound [P] can be more effectively promoted. As a result, the pattern rectangularity can be improved.

As the metal compound (1), a metal halide compound is preferable, and isopropyltin trichloride or benzyltin trichloride is more preferable.

Examples of the method for performing a hydrolysis condensation reaction on the metal compound (1) include a method in which the metal compound (1) is stirred in water or a solvent containing water in the presence of a base such as tetramethylammonium hydroxide, which is used as necessary. In this case, another compound having a hydrolyzable group may be added, as necessary. The lower limit of the amount of water used in the hydrolysis condensation reaction is preferably 0.2 times mol, more preferably 1 time mol, and still more preferably 3 times mol, in the number of moles, based on the hydrolyzable group of the metal compound (1) and the like. By setting the amount of water in the hydrolysis condensation reaction within the above range, the metal-containing compound [P] can be efficiently obtained.

In the synthesis reaction of the metal-containing compound [P], in addition to the metal compound (1), a compound capable of serving as a multidentate ligand represented by L¹ in the compound of the formula (4), a compound capable of serving as a bridging ligand, or the like may be added. Examples of the compound capable of serving as a bridging ligand include compounds having two or more groups capable of serving as a ligand, such as a hydroxy group, an isocyanate group, an amino group, an ester group, and an amide group.

In the synthesis reaction of the metal-containing compound [P], the lower limit of the temperature is preferably 0° C., and more preferably 10° C. The upper limit of the temperature is preferably 150° C., more preferably 100° C., and still more preferably 50° C.

In the synthesis reaction of the metal-containing compound [P], the lower limit of the time is preferably 1 minute, more preferably 10 minutes, and still more preferably 1 hour. The upper limit of the time is preferably 100 hours, more preferably 50 hours, still more preferably 24 hours, and particularly preferably 4 hours.

### (Solvent [Q])

The solvent [Q] is preferably an organic solvent. Specific examples of the organic solvent include organic solvents similar to those exemplified as the solvent [B] in the underlayer film-forming composition for a metal-containing resist described above.

As the solvent [Q], an ether-based solvent is preferable, and propylene glycol monoethyl ether is more preferable.

### (Other Optional Components)

The composition for forming a metal-containing resist film may contain other optional components such as a compound capable of serving as a ligand, and a surfactant, in addition to the metal-containing compound [P] and the solvent [Q].

### (Compound Capable of Serving as Ligand)

Examples of the compound capable of serving as a ligand include compounds capable of serving as a multidentate ligand or a bridging ligand, and specifically include the same compounds as the compounds capable of serving as a multidentate ligand or a bridging ligand exemplified in the synthesis method of the metal-containing compound [P].

### (Surfactant)

The surfactant is a component that exhibits an action of improving coatability, striation, and the like. Examples of the surfactant include nonionic surfactants, including polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. Examples of the product name thereof include KP341 (manufactured by Shin-Etsu Chemical Co., Ltd.), POLYFLOW No. 75, POLYFLOW NO. 95 (both manufactured by Kyoeisha Chemical Co., Ltd.), EFTOP EF301, EFTOP EF303, EFTOP EF352 (all manufactured by Tohkem Products Corporation), MEGAFACE F171, MEGAFACE F173 (both manufactured by DIC), Fluorad FC430, Fluorad FC431 (both manufactured by Sumitomo 3M Limited), ASAHIGUARD AG710, SURFLON S-382, SURFLON SC-101, SURFLON SC-102, SURFLON SC-103, SURFLON SC-104, SURFLON SC-105, SURFLON SC-106 (all manufactured by Asahi Glass Co., Ltd.)

### (Preparation Method of Composition for Forming Metal-Containing Resist Film)

The composition for forming a metal-containing resist film can be prepared, for example, by mixing the metal-containing compound [P], and if necessary, other optional components such as the solvent [Q], in a predetermined ratio, and preferably filtering the obtained mixture through a membrane filter having a pore size of 0.4 μm or less.

### [Exposing Step]

In this step, the metal-containing resist film is exposed to extreme ultraviolet rays (having a wavelength of 13.5 nm or the like, also referred to as “EUV”). This step causes a difference in solubility in a developer between an exposed portion and an unexposed portion of the resist film. The exposure conditions can be appropriately determined depending on the type and the like of the resist film forming material to be used.

In addition, in this step, post-exposure bake (hereinafter also referred to as “PEB”) can be performed in order to improve the performance of the resist film such as resolution, pattern profile, developability, etc. after the exposure. The PEB temperature and PEB time can be appropriately determined according to the type of composition for forming a resist film used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the PEB time is preferably 600 seconds, more preferably 300 seconds.

### [Developing Step]

In this step, at least the exposed metal-containing resist film is developed. Examples of the developer to be used for the development include an aqueous alkaline solution (alkaline developer) and an organic solvent-containing solution (organic solvent developer). For example, in the case of the positive type using an alkaline developer, the exposed portion of the metal-containing resist film has been enhanced in solubility in an alkaline aqueous solution. Therefore, a positive type resist pattern is formed by removing the exposed portion through alkali development. In the case of the negative type using an organic solvent developer, the exposed portion of the metal-containing resist film has been lowered in solubility in an organic solvent. Therefore, a negative type resist pattern is formed by removing the unexposed portion, which is relatively soluble in an organic solvent, through organic solvent development.

The developer used in alkaline development is not particularly limited, and known developers can be used. Examples of developer for alkaline development include an alkaline aqueous solution containing at least one of dissolved alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, and the like. Among these, a TMAH aqueous solution is preferable, and a 2.38% by mass TMAH aqueous solution is more preferable.

Examples of the developer used for organic solvent development include the same developer as those exemplified as the solvent for the underlayer film-forming composition for a metal-containing resist described above. The organic solvent is preferably a ketone-based solvent and an ester-based solvent, and more preferably 2-heptanone and propylene glycol monomethyl ether acetate.

The development of the exposed metal-containing resist film is preferably organic solvent development.

In this step, washing and/or drying may be performed after the development.

### [Step of Forming Pattern of Underlayer Film for Metal-Containing Resist]

In this step, the underlayer film for a metal-containing resist is etched using the resist pattern as a mask to form a pattern of the underlayer film for a metal-containing resist.

The above etching may be dry etching or wet etching, but dry etching is preferred.

Dry etching can be performed using, for example, a known dry etching apparatus. The etching gas used for dry etching can be appropriately selected according to the elemental composition of the underlayer film for a metal-containing resist to be etched, and for example, fluorine-based gases such as CHF₃, CF₄, C₂F₆, C₃F₈ and SF₆, chlorine-based gases such as Cl₂ and BCl₃, oxygen-based gases such as O₂, O₃ and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, and NO, and inert gases such as He, N₂ and Ar are used. These gases can also be mixed and used. For dry etching of the underlayer film for a metal-containing resist, a fluorine-based gas is usually used, and a mixture of a fluorine-based gas, an oxygen-based gas, and an inert gas is preferably used.

### [Etching Step]

In this step, etching is performed using the pattern of the underlayer film for a metal-containing resist as a mask. More specifically, etching is performed one or more times using as a mask the pattern formed in the underlayer film for a metal-containing resist obtained in the step of forming a pattern of the underlayer film for a metal-containing resist to obtain a patterned substrate.

When an organic underlayer film is formed on the substrate, the organic underlayer film is etched using the pattern of the underlayer film for a metal-containing resist as a mask to form a pattern of the organic underlayer film, and then the substrate is etched using this organic underlayer film pattern as a mask. Thus, a pattern is formed on the substrate.

The above etching may be dry etching or wet etching, but dry etching is preferred.

Dry etching for forming a pattern on the organic underlayer film can be performed using a known dry etching apparatus. The etching gas used for dry etching can be appropriately selected depending on the elemental composition of the underlayer film for a metal-containing resist and the organic underlayer film to be etched. As the etching gas, the gas for etching the underlayer film for a metal-containing resist described above can be suitably used, and these gases can also be mixed and used. An oxygen-based gas is usually used for dry etching of the organic underlayer film using the pattern of the underlayer film for a metal-containing resist as a mask.

Dry etching for forming a pattern on the substrate using the organic underlayer film pattern as a mask can be performed using a known dry etching apparatus. The etching gas used for dry etching can be appropriately selected depending on the elemental composition of the underlayer film for a metal-containing resist and the substrate to be etched, and the like. For example, etching gases similar to those exemplified as the etching gas used for the dry etching of the organic underlayer film may be used. Etching may be performed a plurality of times with different etching gases. Etching may be performed a plurality of times with different etching gases. After the etching, a semiconductor substrate having a prescribed pattern can be manufactured.

### <<Underlayer Film-Forming Composition for Metal-Containing Resist>>

The underlayer film-forming composition for a metal-containing resist includes the compound [A] and the solvent [B]. As the composition, the underlayer film-forming composition for a metal-containing resist to be used in the above-described method for manufacturing a semiconductor substrate can be suitably employed.

### EXAMPLES

Hereinafter, Examples are described. The following Examples merely illustrate typical Examples of the present invention, and the Examples should not be construed to narrow the scope of the present invention.

In the present Examples, the weight-average molecular weight (Mw) of the compound [A], the concentration of a solution of the compound [A], and the average thickness of a film were measured by the following methods.

### [Weight-Average Molecular Weight (Mw)]

The weight-average molecular weight (Mw) of the compound [A] was measured by gel permeation chromatography (GPC) using GPC columns, available from Tosoh Corporation (“G2000HXL”×2, “G3000HXL”×1, and “G4000HXL”×1) under the following conditions.
Eluant: tetrahydrofuran (manufactured by Wako Pure Chemical Industries, Ltd.)
Flow rate: 1.0 mL/min
Sample concentration: 1.0% by mass
Sample injection amount: 100 μL
Column temperature: 40° C.
Detector: differential refractometer
Standard substance: monodisperse polystyrene

### [Concentration of Solution of Compound [A]]

The concentration (% by mass) of a solution of the compound [A] was calculated by firing 0.5 g of the solution of the compound [A] at 250° C. for 30 minutes, measuring a mass of a residue thus obtained, and dividing the mass of the residue by the mass of the solution of the compound [A].

### [Average Thickness of Film]

The average thickness of the film was measured by using a spectroscopic ellipsometer (“M2000D”, available from J. A. WOOLLAM CO.). More specifically, thicknesses of the film formed on a silicon wafer were measured at optional nine points located at an interval of 5 cm including the center of the film, and the average value of the film thicknesses was calculated, and taken as the average thickness.

### Synthesis of Compound [A]

The monomers used for synthesis in Synthesis Examples 1-1 to 1-17 and Comparative Synthesis Example 1-1 (hereinafter also referred to as “monomers (M-1) to (M-13)”) are shown below. In addition, in the following Synthesis Examples 1-1 to 1-17 and Comparative Synthesis Example 1-1, mol % means a value taken where the total number of moles of silicon atoms in the monomers (M-1) to (M-13) is 100 mol %.

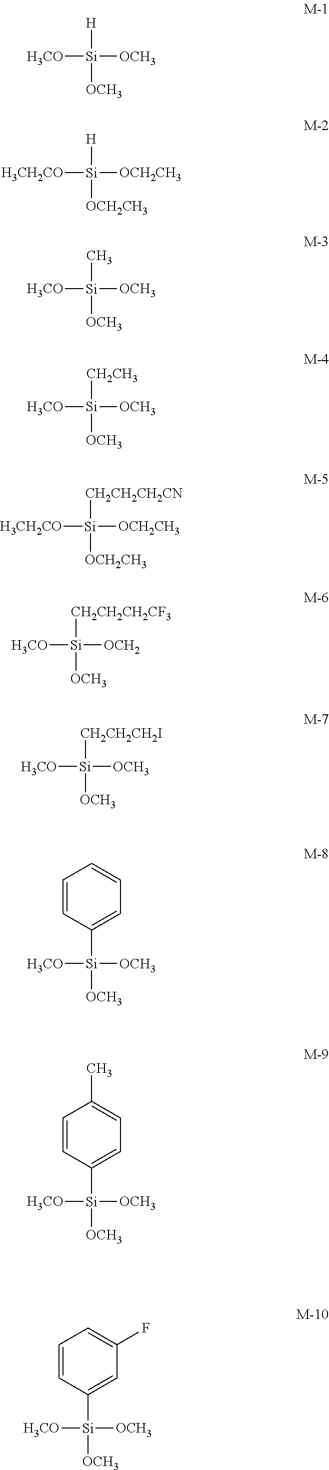

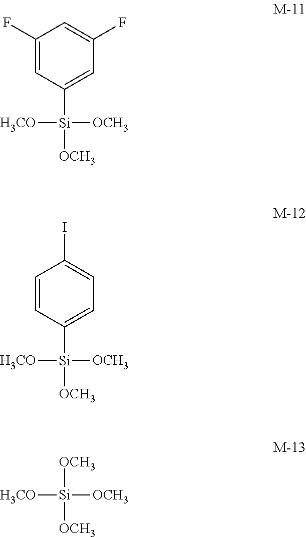 [SMILES: CO[Si](OC)(OC)c1cc(F)cc(F)c1 ; CO[Si](OC)(OC)c1ccc(I)cc1 ; CO[Si](OC)(OC)OC]

### [Synthesis Example 1-1] (Synthesis of Compound (A-1))

Into a reaction vessel, 35.0 g in total of the compound 5 (M-1) and the compound (M-13) were added to be 90 mol % and 10 mol %, respectively, and 104 g of methyl isobutyl ketone and 21.43 g of methanol were further added. The temperature in the reaction vessel was adjusted to 50° C., and 33.34 g of a 3.2% by mass aqueous solution of oxalic acid was added dropwise 10 thereto over 20 minutes with stirring. A time point of completion of the dropwise addition was taken as a start time of a reaction, and the mixture was reacted at 80° C. for 4 hours. Then the inside of the reaction vessel was cooled to 30° C. or lower. Next, 171 g of methyl isobutyl ketone and 515 g of water were added to this reaction vessel, and liquid separation extraction was performed. Thereafter, to the obtained organic layer was added 343 g of propylene glycol monoethyl ether, and then water, diisopropyl ether, alcohols produced by the reaction, and excessive propylene glycol monoethyl ether were removed with an evaporator, affording a solution of compound (A-1) in propylene glycol monoethyl ether. The Mw of the compound (A-1) was 3,500. The concentration of the solution of the compound (A-1) in propylene glycol monoethyl ether was 12% by mass.

### [Synthesis Examples 1-2 to 1-17 and Comparative Synthesis Example 1-1] (Synthesis of Compounds (A-2) to (A-17) and (AJ-1))

Solutions in propylene glycol monoethyl ether of compounds (A-2) to (A-17) and (AJ-1) as the compound [A] were obtained in the same manner as in Synthesis Example 1-1 except that the compounds and the monomers of the types and amounts shown in the following Table 1 were used. The “-” in the columns of monomers in the following Table 1 indicates that the corresponding monomer was not used. The concentration (% by mass) of the obtained solutions of the compound [A] and the Mw of the compound [A] are also shown in Table 1.

TABLE 1

| | Compound | Charged amount of each monomer (mol %) | | | | | | | | | | | | | Concentration | |
|---|---|---|---|---|---|---|---|---|---|---|---|---|---|---|---|---|
| | [A] | M-1 | M-2 | M-3 | M-4 | M-5 | M-6 | M-7 | M-8 | M-9 | M-10 | M-11 | M-12 | M-13 | (% by mass) | Mw |
| Synthesis | A-1 | 90 | — | — | — | — | — | — | — | — | — | — | — | 10 | 12 | 3,500 |
| Example 1-1 | | | | | | | | | | | | | | | | |
| Synthesis | A-2 | 50 | — | — | — | — | — | — | — | — | — | — | — | 50 | 12 | 3,500 |
| Example 1-2 | | | | | | | | | | | | | | | | |
| Synthesis | A-3 | 50 | — | 50 | — | — | — | — | — | — | — | — | — | — | 12 | 2,450 |
| Example 1-3 | | | | | | | | | | | | | | | | |
| Synthesis | A-4 | 50 | — | 25 | — | — | — | — | — | — | — | — | — | 25 | 12 | 2,700 |
| Example 1-4 | | | | | | | | | | | | | | | | |
| Synthesis | A-5 | 30 | — | 40 | — | — | — | — | — | — | — | — | — | 30 | 12 | 2,500 |
| Example 1-5 | | | | | | | | | | | | | | | | |
| Synthesis | A-6 | 10 | — | 20 | — | — | — | — | — | — | — | — | — | 70 | 12 | 2,400 |
| Example 1-6 | | | | | | | | | | | | | | | | |
| Synthesis | A-7 | 5 | — | 15 | — | — | — | — | — | — | — | — | — | 80 | 12 | 2,150 |
| Example 1-7 | | | | | | | | | | | | | | | | |
| Synthesis | A-8 | 5 | — | — | 15 | — | — | — | — | — | — | — | — | 80 | 12 | 2,100 |
| Example 1-8 | | | | | | | | | | | | | | | | |
| Synthesis | A-9 | 5 | — | — | — | 15 | — | — | — | — | — | — | — | 80 | 12 | 2,000 |
| Example 1-9 | | | | | | | | | | | | | | | | |
| Synthesis | A-10 | 5 | — | — | — | — | 15 | — | — | — | — | — | — | 80 | 12 | 2,000 |
| Example 1-10 | | | | | | | | | | | | | | | | |
| Synthesis | A-11 | 5 | — | — | — | — | — | 15 | — | — | — | — | — | 80 | 12 | 2,050 |
| Example 1-11 | | | | | | | | | | | | | | | | |
| Synthesis | A-12 | 5 | — | — | — | — | — | — | 15 | — | — | — | — | 80 | 12 | 1,850 |
| Example 1-12 | | | | | | | | | | | | | | | | |
| Synthesis | A-13 | 5 | — | — | — | — | — | — | — | 15 | — | — | — | 80 | 12 | 1,800 |
| Example 1-13 | | | | | | | | | | | | | | | | |
| Synthesis | A-14 | 5 | — | — | — | — | — | — | — | — | 15 | — | — | 80 | 12 | 1,900 |
| Example 1-14 | | | | | | | | | | | | | | | | |
| Synthesis | A-15 | 5 | — | — | — | — | — | — | — | — | — | 15 | — | 80 | 12 | 1,850 |
| Example 1-15 | | | | | | | | | | | | | | | | |
| Synthesis | A-16 | 5 | — | — | — | — | — | — | — | — | — | — | 15 | 80 | 12 | 1,850 |
| Example 1-16 | | | | | | | | | | | | | | | | |
| Synthesis | A-17 | — | 5 | 15 | — | — | — | — | — | — | — | — | — | 80 | 12 | 2,050 |
| Example 1-17 | | | | | | | | | | | | | | | | |
| Comparative | AJ-1 | — | — | 20 | — | — | — | — | — | — | — | — | — | 80 | 12 | 2,100 |
| Synthesis | | | | | | | | | | | | | | | | |
| Example 1-1 | | | | | | | | | | | | | | | | |

### <Preparation of Underlayer Film-Forming Composition for Metal-Containing Resist>

The components other than water [D] used for the preparation of the underlayer film-forming composition for a metal-containing resist are shown below. In the following Examples 1-1 to 1-21 and Comparative Example 1-1, unless otherwise specified, part(s) by mass represents a value taken where the total mass of the components used is 100 parts by mass.

### Compound [A] and Comparative Compound

A-1 to A-17: Compounds (A-1) to (A-17) synthesized above
AJ-1: Compound (AJ-1) synthesized above for comparison

### [Solvent [B]]

B-1: Propylene glycol monomethyl ether acetate
B-2: Propylene glycol monomethyl ether

### [Other Optional Component [C]]

C-1 (Ortho ester): Trimethyl orthoformate (the compound represented by formula (C-1))
C-2 (Acid generator): Compound represented by formula (C-2) (in the formula, “Bu” represents an n-butyl group)
C-3 (Basic compound): Compound represented by formula (C-3)

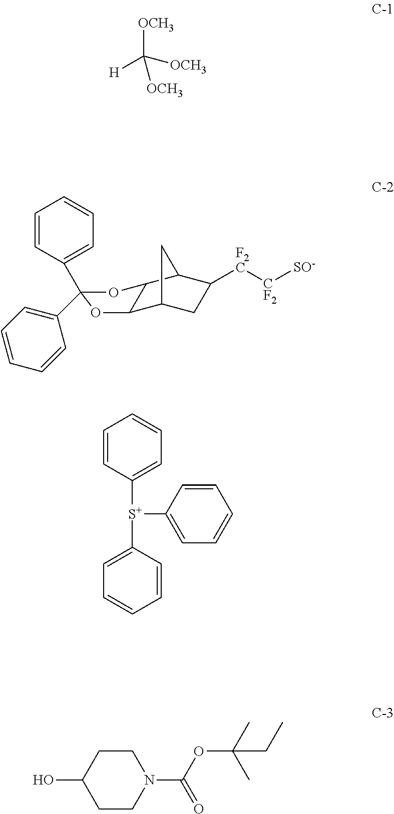

### [Example 1-1] (Preparation of Underlayer Film-Forming Composition (J-1) for Metal-Containing Resist)

An underlayer film-forming composition (J-1) for a metal-containing resist was prepared by mixing 0.50 parts by mass of (A-1) (excluding the solvent) as the compound [A], 9.45 parts by mass of (B-1) (including the solvent (B-1) contained in the solution of the compound [A]) and 85.05 parts by mass of (B-2) as the solvent [B], and 5.00 parts by mass of water [D], and filtering the resulting solution through a polytetrafluoroethylene (PTFE) membrane filter having a pore size of 0.2 μm.

### [Examples 1-2 to 1-21, Comparative Example 1-1] (Preparation of Underlayer Film-Forming Compositions (J-2) to (J-21) and (j-1) for Metal-Containing Resist)

Compositions (J-2) to (J-21) of Examples 1-2 to 1-21 and composition (j-1) of Comparative Example 1-1 were prepared in the same manner as in Example 1-1 except that the respective components of the types and blending amounts shown in the following Table 2 were used. “-” in the following Table 2 indicates that the corresponding component was not used.

### Evaluation

Using the underlayer film-forming composition for a metal-containing resist prepared as described above, the rectangularity of a resist pattern was evaluated by the following method. The evaluation results are shown in the following Table 2.

### <Preparation of Resist Composition (R-1)>

### Synthesis of Metal-Containing Compound

The compound (S-1) as the metal-containing compound to be used for the preparation of the resist composition (R-1) was synthesized by the following procedure. Into a reaction vessel, 6.5 parts by mass of isopropyltin trichloride were added while stirring 150 mL of a 0.5 N aqueous sodium hydroxide solution, and stirring was carried out for 2 hours.

The precipitate formed was collected by filtration, washed twice with 50 parts by mass of water, and then dried to obtain a compound (S-1). The compound (S-1) was an oxidized hydroxide product of a hydrolysate of isopropyltin trichloride (the oxidized hydroxide product contained i-PrSnO_{(3/2-x/2)} (OH)ₓ (0<x<3) as a structural unit).

Mixed were 2 parts by mass of the compound (S-1) synthesized above and 98 parts by mass of propylene glycol monoethyl ether, and the obtained mixture was subjected to removal of residual water with activated 4 Å molecular sieve, and then filtered through a polytetrafluoroethylene (PTFE) membrane filter having a pore size of 0.2 μm. Thus, a resist composition (R-1) was prepared.

### [Resist Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Limited), and thereafter heating was conducted at 250° C. for 60 sec to form an organic underlayer film having an average thickness of 100 nm. To the organic underlayer film was applied the underlayer film-forming composition for a metal-containing resist prepared above, heated at 220° C. for 60 seconds, and then cooled at 23° C. for 30 seconds. Thus, an underlayer film for a metal-containing resist having an average thickness of 5 nm was formed. The underlayer film for a metal-containing resist was coated with the resist composition (R-1) by the spin coating method using a spin coater described above, and after a lapse of a prescribed time, heated at 90° C. for 60 seconds, and then cooled at 23° C. for 30 seconds. Thus, a resist film having an average thickness of 35 nm was formed. The resist film was exposed to light using an EUV scanner (“TWINSCAN NXE: 3300B”, available from ASML Co. (NA=0.3; Sigma=0.9; quadrupole illumination, with a 1:1 line and space mask having a line width of 25 nm in terms of a dimension on wafer)). After the exposure, the substrate was heated at 110° C. for 60 seconds, and subsequently cooled at 23° C. for 60 seconds. Thereafter, development was performed by a paddle method using Dev-1:2-heptanone (20 to 25° C.) or Dev-2: propylene glycol monomethyl ether acetate (20 to 25° C.) as a developer, and drying was then performed to obtain a substrate for evaluation on which a resist pattern was formed. A scanning electron microscope (“SU8220” available from Hitachi High-Tech Corporation) was used for length measurement and observation of the resist pattern of the substrate for evaluation. The pattern rectangularity was evaluated as “A” (good) when the cross-sectional shape of the pattern was rectangular, “B” (slightly good) when trailing was present in the cross-sectional shape of the pattern, and “C” (poor) when a residue (defect) was present in the pattern.

TABLE 2

| | Underlayer | | | | | Other optional | | | | |
|---|---|---|---|---|---|---|---|---|---|---|
| | film-forming | Compound [A] | | Solvent [B] | | component [C] | | Water [D] | | |
| | composition | | Blending | | Blending | | Blending | Blending | Resist pattern | Resist pattern |
| | for a metal- | | amount | | amount | | amount | amount | rectangularity | rectangularity |
| | containing | | (parts by | | (parts by | | (parts by | (parts by | Developer: | Developer: |
| | resist | Type | mass) | Type | mass) | Type | mass) | mass) | Dev-1 | Dev-2 |
| Example 1-1 | J-1 | A-1 | 0.50 | B-1/B-2 | 9.45/85.05 | — | — | 5.00 | B | B |
| Example 1-2 | J-2 | A-2 | 0.50 | B-1/B-2 | 9.45/85.05 | — | — | 5.00 | A | A |
| Example 1-3 | J-3 | A-3 | 0.50 | B-1/B-2 | 9.45/85.05 | — | — | 5.00 | A | A |
| Example 1-4 | J-4 | A-4 | 0.50 | B-1/B-2 | 9.45/85.05 | — | — | 5.00 | A | A |
| Example 1-5 | J-5 | A-5 | 0.50 | B-1/B-2 | 9.45/85.05 | — | — | 5.00 | A | A |
| Example 1-6 | J-6 | A-6 | 0.50 | B-1/B-2 | 9.45/85.05 | — | — | 5.00 | A | A |
| Example 1-7 | J-7 | A-7 | 0.50 | B-1/B-2 | 9.45/85.05 | — | — | 5.00 | A | A |
| Example 1-8 | J-8 | A-7 | 0.50 | B-2 | 94.50 | — | — | 5.00 | A | A |
| Example 1-9 | J-9 | A-7 | 0.50 | B-1/B-2 | 9.45/85.05 | C-1 | 3 | 5.00 | A | A |
| Example 1- | J-10 | A-7 | 0.50 | B-1/B-2 | 9.45/85.05 | C-2 | 3 | 5.00 | A | A |
| 10 | | | | | | | | | | |
| Example 1- | J-11 | A-7 | 0.50 | B-1/B-2 | 9.45/85.05 | C-3 | 3 | 5.00 | A | A |
| 11 | | | | | | | | | | |
| Example 1- | J-12 | A-8 | 0.50 | B-1/B-2 | 9.45/85.05 | — | — | 5.00 | A | A |
| 12 | | | | | | | | | | |
| Example 1- | J-13 | A-9 | 0.50 | B-1/B-2 | 9.45/85.05 | — | — | 5.00 | A | A |
| 13 | | | | | | | | | | |
| Example 1- | J-14 | A-10 | 0.50 | B-1/B-2 | 9.45/85.05 | — | — | 5.00 | A | A |
| 14 | | | | | | | | | | |
| Example 1- | J-15 | A-11 | 0.50 | B-1/B-2 | 9.45/85.05 | — | — | 5.00 | A | A |
| 15 | | | | | | | | | | |
| Example 1- | J-16 | A-12 | 0.50 | B-1/B-2 | 9.45/85.05 | — | — | 5.00 | A | A |
| 16 | | | | | | | | | | |
| Example 1- | J-17 | A-13 | 0.50 | B-1/B-2 | 9.45/85.05 | — | — | 5.00 | A | A |
| 17 | | | | | | | | | | |
| Example 1- | J-18 | A-14 | 0.50 | B-1/B-2 | 9.45/85.05 | — | — | 5.00 | A | A |
| 18 | | | | | | | | | | |
| Example 1- | J-19 | A-15 | 0.50 | B-1/B-2 | 9.45/85.05 | — | — | 5.00 | A | A |
| 19 | | | | | | | | | | |
| Example 1- | J-20 | A-16 | 0.50 | B-1/B-2 | 9.45/85.05 | — | — | 5.00 | A | A |
| 20 | | | | | | | | | | |
| Example 1- | J-21 | A-17 | 0.50 | B-1/B-2 | 9.45/85.05 | — | — | 5.00 | A | A |
| 21 | | | | | | | | | | |
| Comparative | j-1 | AJ-1 | 0.50 | B-1/B-2 | 9.45/85.05 | — | — | 5.00 | C | C |
| Example 1-1 | | | | | | | | | | |

As is apparent from the results in Table 3, the underlayer films for a metal-containing resist formed from the compositions of Examples successfully exhibited excellent pattern rectangularity as compared with the underlayer films for a metal-containing resist formed from the compositions of Comparative Examples.

The method for manufacturing a semiconductor substrate and the underlayer film-forming composition for a metal-containing resist according to the present disclosure can form an underlayer film for a metal-containing resist with excellent pattern rectangularity. Therefore, these can be suitably used for manufacturing the semiconductor substrate and the like.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
applying an underlayer film-forming composition directly or indirectly to a substrate to form an underlayer film;
forming a metal-containing resist film on the underlayer film;
exposing the metal-containing resist film to extreme ultraviolet rays; and
developing the exposed metal-containing resist film,
wherein the underlayer film-forming composition comprises:
a compound comprising a structural unit (α) represented by formula (1-1); and
a solvent: 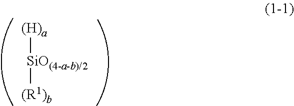
wherein in the formula (1-1), a is an integer of 1 to 3; R¹ is a monovalent organic group having 1 to 20 carbon atoms, a hydroxy group, or a halogen atom; b is an integer of 0 to 2; when b is 2, two R¹s are the same or different from each other; provided that a+b is 3 or less.

2. The method according to claim 1, wherein the compound is polysiloxane.

3. The method according to claim 1, wherein a content ratio of the structural unit (α) in the compound to all structural units constituting the compound is 0.1 mol % or more and 90 mol % or less.

4. The method according to claim 1, wherein the metal-containing resist film is formed from a composition for forming a metal-containing resist film; and
the composition for forming a metal-containing resist film comprises: a metal-containing compound; and a solvent, and a content ratio of the metal-containing compound in the composition to components other than the solvent in the composition is 50% by mass or more.

5. The method according to claim 1, wherein developing comprises developing the exposed metal-containing resist film with an organic solvent.

6. The method according to claim 1, wherein the underlayer film has a film thickness of 6 nm or less.

7. A underlayer film-forming composition comprising:
a compound comprising a structural unit (α) represented by formula (1-1); and
a solvent: 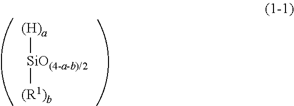
wherein in the formula (1-1), a is an integer of 1 to 3; R¹ is a monovalent organic group having 1 to 20 carbon atoms, a hydroxy group, or a halogen atom; b is an integer of 0 to 2; when b is 2, two R¹s are the same or different from each other; provided that a+b is 3 or less.

8. The underlayer film-forming composition according to claim 7, wherein the compound is polysiloxane.

9. The underlayer film-forming composition according to claim 7, wherein a content ratio of the structural unit (α) in the compound to all structural units constituting the compound is 0.1 mol % or more and 90 mol % or less.

10. The underlayer film-forming composition according to claim 7, wherein
the underlayer film is suitable for an underlayer film for a metal-containing resist film,
the metal-containing resist film is formed from a composition for forming a metal-containing resist film, and
the composition for forming a metal-containing resist film comprises: a metal-containing compound; and a solvent, and a content ratio of the metal-containing compound in the composition to components other than the solvent in the composition is 50% by mass or more.
